(19) United States
(12) Patent Application Publication
(10) Pub. No.: US 2009/0085124 A1
(43) Pub. Date: Apr. 2, 2009

(54) Semiconductor storage device and manufacturing method of the same

(75) Inventor: Hitoshi Abiko, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/232,643

(22) Filed: Sep. 22, 2008

(30) Foreign Application Priority Data
Oct. 2, 2007 (JP) 2007-258848

(51) Int. Cl. H01L 29/00; H01L 21/425

(52) U.S. Cl. 257/369; 438/527; 257/E29.001; 257/E21.473

(57) ABSTRACT

A semiconductor storage device includes: a storage circuit, an access control circuit, a ground voltage supplying region, and a polysilicon portion. The storage circuit stores data. The access control circuit includes a first access transistor and a second access transistor and controls reading and writing of the data. The ground voltage supplying region supplies a ground voltage to the storage circuit and the access control circuit. The polysilicon portion connects a first gate electrode included in the first access transistor and a second gate electrode included in the second access transistor, and is composed of a semiconductor of a second conductive type. The ground voltage supplying region is connected to a ground voltage supplying contact which supplies the ground voltage, and includes: a first portion composed of a semiconductor of the second conductive type, and a second portion composed of a semiconductor of a first conductive type.

### INCORPORATION BY REFERENCE

This application is based upon and claims the benefit of priority from Japanese patent application No. 2007-258848 filed on Oct. 2, 2007, the disclosure of which is incorporated herein in its entirety by reference.

### BACKGROUND OF THE INVENTION

1. Field of the Invention

The present invention relates to a semiconductor storage device and a manufacturing method of the same.

2. Description of Related Art

Various electronic devices having become prevalent currently use a RAM (Random Access Memory) that is an information storage device. As the RAM, a SRAM (Static RAM) operating at a high speed, a DRAM (Dynamic RAM) having an operating speed lower than that of the SRAM and the like are known. The SRAM is used, for example, for a cache memory inside a chip of a microprocessor, a memory for a mobile device and the like. The SRAM has a plurality of SRAM cells arranged in an array. Each of the plurality of SRAM cells includes a flip-flop circuit for performing storage and a switch transistor. The flip-flop circuit of the SRAM cell having currently prevailed includes an inverter composed of a CMOS (Complementary Metal Oxide Semiconductor).

FIG. 1 is a layout pattern diagram illustrating a configuration of a general SRAM device 101. As described above, a plurality of SRAM cells 102 are arranged in an array in the SRAM device 101. Moreover, the SRAM device 101 includes a P-type semiconductor substrate 103 and an N-type impurity diffusion layer (hereinafter, referred to as an N-well 104). The P-type semiconductor substrate 103 is connected to a substrate contact 106. The substrate contact 106 supplies a ground voltage (called a ground voltage GND) to the P-type semiconductor substrate 103. Moreover, the N-well 104 is connected to an N-well contact 105. The N-well contact 105 supplies a power supply voltage (referred to as a power supply voltage VCC) to the N-well 104.

FIG. 2 is a layout pattern diagram exemplifying a configuration of the SRAM cell 102 included in the SRAM device 101. The SRAM cell 102 is a 6-transistor type SRAM circuit, and includes a flip-flop circuit 107 and a switch transistor 108. The flip-flop circuit 107 includes a first inverter 111 and a second inverter 112. The first inverter 111 (or the second inverter 112) includes a P-channel MOSFET (Metal Oxide Semiconductor Field Effect Transistor) 113 in the N-well 104, and an N-channel MOSFET 114 in the P-type semiconductor substrate 103. The switch transistor 108 includes a first switch NMOSFET 115 and a second switch NMOSFET 116.

FIG. 3 shows an equivalent circuit showing a configuration of the SRAM cell 102. The SRAM cell 102 includes a word line 117, a bit line 118, and a bit line 119. A gate electrode of the first switch NMOSFET 115 and a gate electrode of the second switch NMOSFET 116 are both connected to the word line 117. The bit line 118 is connected to the first switch NMOSFET 115, and the bit line 119 is connected to the second switch NMOSFET 116.

As shown in FIG. 3, a source electrode of the P-channel MOSFET 113 is connected to a power supply voltage supplying node 121. A source electrode of the N-channel MOSFET 114 is connected to a ground voltage supplying node 122. An output terminal of the first inverter 111 is connected to an input terminal of the second inverter 112 and the first switch NMOSFET 115. Similarly, an output terminal of the second inverter 112 is connected to an input terminal of the first inverter 111 and the second switch NMOSFET 116.

FIG. 4 is a sectional view showing a configuration of a general CMOS type semiconductor device. In the CMOS type semiconductor device, the N-well 104 is formed in the P-type semiconductor substrate 103, and a PMOSFET is formed in the N-well 104. A NMOSFET is formed in the P-type semiconductor substrate 103 (or in a region that is not the N-well 104, e.g., a P-well). The ground voltage GND is applied to a source of the NMOSFET, and the power supply voltage VCC is applied to a source of the PMOSFET.

Thereby, a PN junction of the P-type semiconductor substrate 103 and the N-well 104 becomes reverse biased. Moreover, the source of the PMOSFET in the N-well 104 and the N-well 104 become at a same voltage. Furthermore, the source of the NMOSFET in the P-type semiconductor substrate 103 and the inside of the P-type semiconductor substrate 103 also become at the same voltage. A drain of the PMOSFET is at a voltage between the power supply voltage VCC and the ground voltage GND. Similarly, a drain of the NMOSFET is also at a voltage between the power supply voltage VCC and the ground voltage GND. Therefore, a PN junction of the drain of the PMOSFET in the N-well 104 and the N-well 104 becomes reverse biased. Moreover, a PN junction of the drain of the NMOSFET in the P-type semiconductor substrate 103 and the P-type semiconductor substrate 103 also becomes reverse biased.

FIG. 5 is an energy band diagram showing an energy distribution of the CMOS semiconductor device shown in FIG. 4. FIG. 5 shows a state of energy along a dashed line of FIG. 4 in the CMOS semiconductor device. Referring to the energy band diagram, it shows that none of the PN junctions of the CMOS semiconductor device becomes forward biased as described above.

Here, in FIG. 1, an operation of the CMOS semiconductor device will be explained, for example, corresponding to a situation where a power supply voltage VCC of 1V is supplied to the SRAM device 101 through the N-well contact 105 and a ground voltage GND of 0 V is supplied to the SRAM device 101 through the substrate contact 106. FIG. 6 is a plan view showing conceptually a configuration of the SRAM device 101 to which a power supply voltage VCC of 1 V and the ground voltage GND of 0 V are supplied. Each of the plurality of SRAM cells 102 constituting the SRAM device 101 includes a PMOSFET 125 and an NMOSFET 126. In here, it is assumed that a sub-threshold current value of the NMOSFET 126 is 1 microampere and an effective resistance value from the NMOSFET 126 to the substrate contact 106 (a second resistor 124) is 600 kilohms. It is further assumed that a sub-threshold current value of the PMOSFET 125 is 1 microampere and an effective resistance value from the PMOSFET 125 to the N-well contact 105 (a first resistor 123) is 600 kilohms.

As shown in FIG. 6, the N-well contact 105 and the substrate contact 106 are constructed corresponding to the plurality of SRAM cells 102. In this case, in the SRAM cell 102 constructed at a position away from the substrate contact 106, a voltage of the P-type semiconductor substrate 103 becomes about 0.6 V in the vicinity of the NMOSFET 126. Moreover, in the SRAM cell 102 constructed at a position away from the N-well contact 105, a voltage of the N-well 104 becomes about 0.4 V in the vicinity of the PMOSFET 125. Consequently, the P-type semiconductor substrate 103 and the N-well 104 may be biased in a forward direction at a boundary of the NMOSFET 126 and the PMOSFET 125. At this time, a phenomenon occurs in which a large current begins to flow from the N-well 104 of the CMOS semiconductor device to the P-type semiconductor substrate 103 (hereinafter, called a latchup phenomenon).

FIG. 7 is an energy band diagram showing an energy distribution when the latchup phenomenon has occurred. The energy band diagram shows the energy distribution in a case where the power supply voltage VCC of 1 V is supplied through the N-well contact 105, and the ground voltage GND of 0 V is supplied through the substrate contact 106. Moreover, the energy band diagram shows a state of an energy distribution along the dashed line of FIG. 4. At this time, in the CMOS semiconductor device constructed at a position away from the substrate contact 106 (or the N-well contact 105), all the PN junctions are forward biased, and the latchup phenomenon occurs. Incidentally, a cause for occurring the latchup is not limited to the substrate current by hot carriers described above, and the latchup might occur by other causes such as power supply noise.

As described above, in the CMOS semiconductor device, the latchup occurs because the P-type semiconductor substrate 103 and the N-well 104, which should be reverse biased, become forward biased locally. That is, it occurs because a PN junction, which has been reverse-biased, is forward biased by carriers, which are generated for some reason, flowing as far as to the substrate contact 106 (or the N-well contact 105).

Therefore, in the SRAM device 101, it is possible to suppress an occurrence of latchup by increasing the number of the substrate contact 106 and the N-well contact 105, and arranging the substrate contact 106 and the N-well contact 105 in the vicinity of the MOSFET 126 and the PMOSFET 125. For example, it becomes possible to decrease an occurrence of latchup by arranging one substrate contact 106 and one N-well contact 105 in each cell. However, in this case, an area of the cell array will become larger than before. In this sort of SRAM, it is necessary to make the area of the cell array as small as possible from a viewpoint of cost reduction. A technique is known which can improve latchup resistance without increasing the area of the cell array.

Japanese Laid-Open Patent Application JP-P 2005-159131A (U.S. Pat. No. 7,250,661 (B2)) describes a method of forming a substrate contact in a part of a GND contact of each cell as a technique of suppressing latchup. FIGS. 8A and 8B are diagrams showing one process in a manufacture method of a semiconductor storage device described in JP-P 2005-159131A. FIG. 8A is a plan view of the semiconductor storage device, and FIG. 8B is a sectional view of the semiconductor storage device.

Referring to FIG. 8A, in the technique described in JP-P 2005-159131A, an STI (Shallow Trench Isolation) 202 is formed as an element isolation region, and subsequently a mask using a resist pattern is formed. Then, P-type impurities, such as B (boron), are selectively introduced into a P-type well region 204 by ion implantation using the resist pattern. Moreover, N-type impurities, such as P (phosphorus) or As (arsenic), are selectively introduced into an N-type well region 205. In this way, a high-concentration P-type region 206 for supplying the ground potential and a high-concentration N-type region 207 for supplying a power supply potential are formed.

With the technique of JP-P 2005-159131A, the resist pattern described above is constructed so that openings may be opened by photolithography in at least a part of a region where the GND contact is formed and a part of a region where the VCC contact is formed. FIG. 8B shows a sectional view at this time. As shown in FIG. 8B, the high-concentration P-type region 206 for supplying the ground potential serves as a part of a path that connects VSS to the P-type well region 204, and similarly the high-concentration N-type region 207 for supplying a power supply potential serves as a part of a path that connects VDD to the N-type well region 205.

FIG. 9A is a plan view showing another process of the manufacturing method of the semiconductor storage device described in JP-P 2005-159131A. In the manufacturing method of the semiconductor storage device described in JP-P 2005-159131A, as shown in FIG. 9A, after a contact opening is opened, a mask using the resist pattern is formed such that a GND contact is opened by photolithography, and the impurities forming a P-type diffusion layer are ion-implanted with a deeper depth and a higher concentration than impurities of the source and drain.

Next, a mask using the resist pattern is formed such that the VCC contact opens, and the impurities forming an N-type diffusion layer are ion-implanted with a deeper depth and a higher concentration than the impurities of the source and drain, whereby the GND contact and the VCC contact are formed. FIG. 9B shows a sectional view at this time. As shown in FIG. 9B, in the semiconductor device described in JP-P 2005-159131A, an N+ type source/drain region 213 is formed in the P-type well region 204, and the high-concentration P-type region 206 for supplying the ground potential is formed such that it penetrates this N+ type source/drain region 213 and contacts with the P-type well region 204. Moreover, a P+ type source/drain region 214 is formed in the N-type well region 205, and the high-concentration N-type region 207 for supplying a power supply potential is formed such that it penetrates the P+ type source/drain region 214 and contacts with the N-type well region 205. The VSS is connected to the high-concentration P-type region 206 for supplying the ground potential through a Co silicide layer 216, a contact 220A, and an embedded wiring 224A for the VSS. Also, the VDD is connected to the high-concentration N-type region 207 for supplying the power supply potential through the Co silicide layer 216, a contact 220B, and an embedded wiring 224B for the VDD.

Japanese Laid-Open Patent Application JP-P 2005-347360A (U.S. Pat. No. 7,372,105 (B2)) discloses another technique which can improve latchup resistance without increasing the area of the cell array. FIG. 10 is a plan layout diagram showing an SRAM memory cell M-CELL of the semiconductor device described in JP-P 2005-347360A. A region surrounded by dashed lines of FIG. 10 shows one memory cell region. A P-well 301 and an N-well 302 are formed in a silicon substrate 300, and further an element isolation region (STI) 303 is formed therein. A gate electrode 305 of each MOS transistor is formed above the silicon substrate 300 by forming a polysilicon layer with a required pattern. A part of the gate electrode 305 is constructed as a word line. Then, by a self-alignment method using the gate electrode 305, N-type source/drain regions 310 are formed in the P-well 301, and P-type source/drain regions 320 are formed in the N-well 302, respectively. Further, in a part of the N-type source/drain region 310, a GND contact 330 for supplying the VSS potential (here, the GND potential) to the P-well 301 is formed.

In a technique described in JP-P 2005-347360A, after forming the source/drain regions 310, a sidewall of the polysilicon that forms the word line (the gate electrode 305) is removed and substrate etching only to remove an extension region under the sidewall is performed, whereby the GND contact 330 is made to connect the well.

FIG. 11 is a sectional view along a line A-A′ of FIG. 10 including the GND contact 330. The element isolation region (STI) 303 and the P-well 301 are formed in the silicon substrate 300. The N-well 302 is not showed in this figure. On the silicon substrate 300, the gate electrode 305 including a gate insulating film 304 and the polysilicon layer is formed, and on a side surface of the gate electrode 305, a sidewall 306 formed of a silicon oxide film etc. is formed.

Incidentally, a reference numeral “306” is given to the sidewall 306 in FIGS. 11, 12, and 13, and its illustration is omitted in FIG. 10.

The N-type source/drain regions 310 are formed on the both sides of the gate electrode 305 in the P-well 301. The N-type source/drain regions 310 together with the gate electrode 305 constitute each of N-type MOS transistors Q1, Q2, Q5, and Q6. Here, the N-type source/drain region 310 is composed of a low-concentration N− diffusion layer 311 formed right under the sidewall 306 and a high-concentration N+ diffusion layer 312 formed in a region other than right under the side wall 306, as will be explained later in a manufacturing process. That is, each of these transistors is configured as a MOS transistor with a so-called LDD structure. Incidentally, the P-channel MOS transistors Q3 and Q4 are similar to the above, that is, the P-type source/drain region 320 is composed of a low-concentration P− diffusion layer right under the sidewall 306 and a high-concentration P+ diffusion layer in the other region.

FIGS. 12 and 13 are sectional views showing manufacturing processes of the semiconductor device described in JP-P 2005-347360A. When the semiconductor device is manufactured as described in JP-P 2005-347360A, the element isolation region (STI) 303 is formed by embedding an insulating material, such as silicon oxide, in a trench formed in a required region of the silicon substrate 300. Next, the P-type impurities are selectively diffused into the silicon substrate 300 to form the P-well 301. Moreover, the N-type impurities are diffused into other regions of the silicon substrate 300 to form the N-well 302.

In here, referring to FIG. 12, the gate insulating film 304 is formed of a silicon oxide film etc. on the silicon substrate 300, a polysilicon layer is formed thereon, and the polysilicon layer is shaped into the required pattern to form the gate electrode 305. Then, the N− diffusion layers 311 are formed by implanting the N-type impurities with a low concentration in regions where an N-type MOS transistor is to be formed. Furthermore, the P− diffusion layers are formed in regions where a P-type MOS transistor is to be formed by implanting the P-type impurities with a low concentration although not shown in the figure.

Subsequently, a silicon oxide film is grown on the whole surface, and this film is anisotropically etched to form the sidewall 306 on a side surface of the gate electrode. Then, the N-type impurities are implanted with a high concentration in regions where an N-type MOS transistor is to be formed to form the N+ diffusion layers 312. The N-type source/drain regions 310 are formed by these, so that N-type MOS transistors of the LDD structure designated by symbols Q1, Q2, Q5, and Q6 in FIG. 10 are formed. Moreover, the P-type impurities are implanted with a high concentration in regions where a P-type MOS transistor is to be formed to form the P+ diffusion layers, whereby the P-type MOS transistors of the LDD structure are formed, although not shown in the figure.

Referring to FIG. 13, in a subsequent process, a region excluding a region where the GND contact shown by a reference numeral 330 in FIG. 10 is masked with a resist pattern PR and the sidewall 306 is etched. In addition, the silicon substrate 300 is etched until an etched depth reaches a depth of the above-mentioned N− diffusion layer 311. By this process, in the region of the GND contact shown by the reference numeral 330 in FIG. 10, the N-diffusion layer 311 and a part of the N+ diffusion layer 312 adjoining the N-diffusion layer 311 are etched away.

However, we have now discovered the following facts. In the semiconductor device described in JP-P 2005-159131A, the N-type well contact region (namely, the high-concentration N-type region for supplying the power supply potential shown by the reference numeral 207 in FIGS. 8A and 8B) connected to the VDD and the P-type well contact region (namely, the high-concentration P-type region for supplying the ground potential shown by the reference numeral 206 in FIGS. 8A and 8B) connected to the VSS are formed every one bit in the memory cell MC.

In the semiconductor device described in JP-P 2005-347360A, the N− diffusion layer that is an extension and is shown by the reference numeral 311 in FIG. 12 is formed under the sidewall 306 of the gate electrode that is the word line and is shown by the reference numeral 305 in FIGS. 10 to 13. When a part of the diffusion layer including the sidewall 306 is selectively removed, the diffusion layer is removed such that the N− diffusion layer that is the extension and is shown by the reference numeral 311 in FIG. 12 is removed. By this process, the semiconductor device described in JP-P 2005-347360A has the N+ diffusion layer shown by the reference numeral 312 in FIG. 11 and the P+ diffusion layer shown by the reference numeral 331 in FIG. 11 therein.

The techniques described in JP-P 2005-159131A and JP-P 2005-347360A as shown above, have the process of forming the region whose contact is to be connected to the substrate (or the P-well) for each cell. In the process, in order to form the region, anew resist pattern is used. Therefore, in advance of the formation of the resist pattern, manufacture of the photomask will be needed and the cost of manufacturing the photomasks will increase. Moreover, increased number of steps of the manufacturing process lengthens a time consumed for semiconductor manufacturing, which increases a manufacturing cost of an LSI.

### SUMMARY

The present invention seeks to solve one or more of the above problems, or to improve upon those problems at least in part. In one embodiment, a semiconductor storage device includes: a storage circuit, an access control circuit, a ground voltage supplying region, and a polysilicon portion. The storage circuit stores data. The access control circuit includes a first access transistor and a second access transistor and controls reading and writing of the data. The ground voltage supplying region supplies a ground voltage to the storage circuit and the access control circuit. The polysilicon portion connects a first gate electrode included in the first access transistor and a second gate electrode included in the second access transistor, and is composed of a semiconductor of a second conductive type. The ground voltage supplying region is connected to a ground voltage supplying contact which supplies the ground voltage, and includes: a first portion composed of a semiconductor of the second conductive type, and a second portion composed of a semiconductor of a first conductive type.

In another embodiment, a manufacturing method of a semiconductor storage device having a SRAM cell, includes: forming a first photoresist having an opening portion in which a part of a contact connection region in an activated region where a transistor is formed and a polysilicon portion functions as a word line are exposed; implanting first impurities of a second conductive type to the opening portion using the first photoresist as a mask; forming a second photoresist masking a region where the first impurities are implanted; and implanting second impurities of a first conductive type to the contact connection region using the second photoresist as a mask.

In another embodiment, a semiconductor storage device includes: an access control circuit, a ground voltage supplying region, and a word line. The access control circuit includes a first access transistor and a second access transistor and controls reading and writing of data stored in a storage circuit. The ground voltage supplying region supplies a ground voltage to the storage circuit and the access control circuit. The word line has a connection portion which connects a first gate electrode included in the first access transistor and a second gate electrode included in the second access transistor. The ground voltage supplying region includes: a first carrier type semiconductor and a second carrier type semiconductor. The first carrier type semiconductor has first carriers as a majority carrier. The second carrier type semiconductor has second carriers as a majority carrier. The connection portion includes impurities to make the first carriers be a majority carrier.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a layout pattern diagram exemplifying a configuration of a general SRAM device 101;

FIG. 2 is a layout pattern diagram exemplifying a configuration of an SRAM cell 102 included in the SRAM device 101;

FIG. 3 is an equivalent circuit showing a configuration of the SRAM cell 102;

FIG. 4 is a sectional view showing a configuration of a general CMOS type semiconductor;

FIG. 5 is an energy band diagram showing an energy distribution of a CMOS semiconductor device;

FIG. 6 is a plan view showing conceptually the configuration of the SRAM device 101;

FIG. 7 is an energy band diagram showing an energy distribution when a latchup phenomenon occurs;

FIGS. 8A and 8B are diagrams showing a manufacturing process of a semiconductor device of a related art;

FIGS. 9A and 9B are diagrams showing a manufacturing process of the semiconductor device of the related art;

FIG. 10 is a plan layout pattern showing an SRAM memory cell of a semiconductor device of a related art;

FIG. 11 is a sectional view along a line A-A′ of FIG. 10 including a GND contact 330;

FIG. 12 is a sectional view showing a manufacturing process of the semiconductor device of the related art;

FIG. 13 is a sectional view showing a manufacturing process of the semiconductor device of the related art;

FIG. 14 is a plan view exemplifying a layout of the SRAM cell 1 included in the semiconductor storage device of the present embodiment;

FIG. 15 is a sectional view exemplifying the SRAM cell 1 of the present embodiment;

FIG. 16 is a plan view exemplifying a manufacturing process of the SRAM cell 1 of the present embodiment;

FIG. 17 is a sectional view exemplifying the SRAM cell 1 of the present embodiment;

FIG. 18 is a plan view exemplifying the manufacturing process of the SRAM cell 1 of the present embodiment;

FIG. 19 is a sectional view exemplifying the SRAM cell 1 of the present embodiment;

FIG. 20 is a plan view exemplifying the manufacturing process of the SRAM cell 1 of the present embodiment;

FIG. 21 is a sectional view exemplifying the SRAM cell 1 of the present embodiment;

FIG. 22 is a plan view exemplifying the manufacturing process of the SRAM cell 1 of the present embodiment;

FIG. 23 is a sectional view showing a process of forming a sidewall of the present embodiment;

FIG. 24 is a sectional view showing the process of forming the sidewall of the present embodiment;

FIG. 25 is a sectional view showing the process of forming the sidewall of the present embodiment;

FIG. 26 is a plan view exemplifying the manufacturing process of the SRAM cell 1 of the present embodiment;

FIG. 27 is a sectional view exemplifying the SRAM cell 1 of the present embodiment;

FIG. 28 is a plan view exemplifying the manufacturing process of the SRAM cell 1 of the present embodiment;

FIG. 29 is a sectional view exemplifying the SRAM cell 1 of the present embodiment; and

FIG. 30 is a sectional view exemplifying the SRAM cell 1 of the present embodiment.

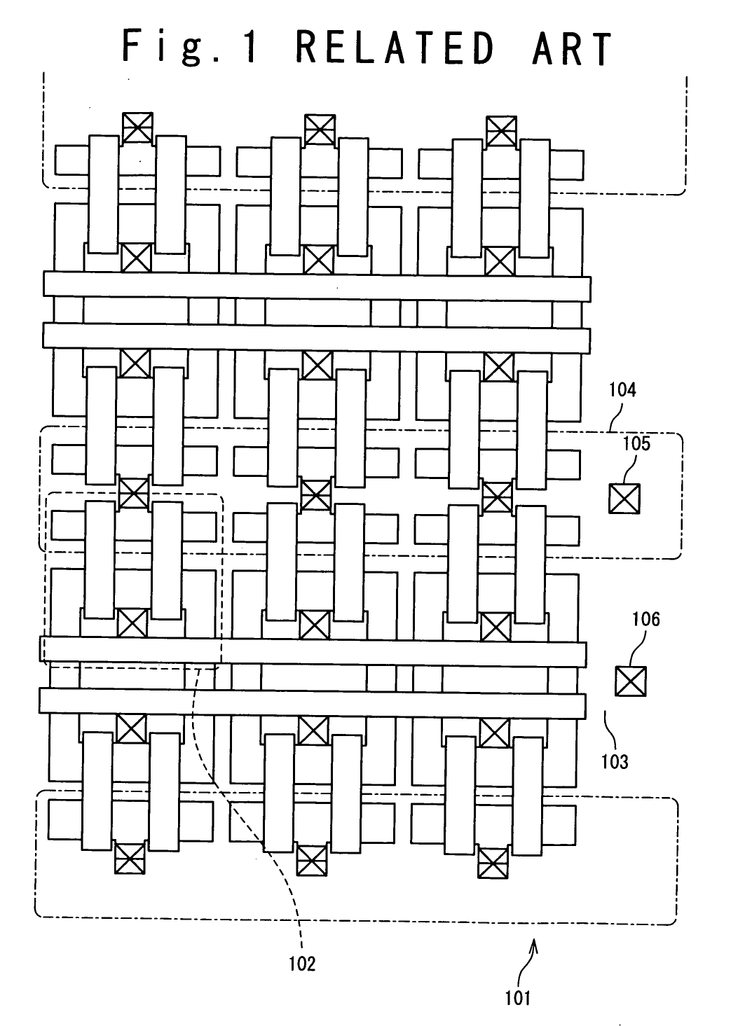

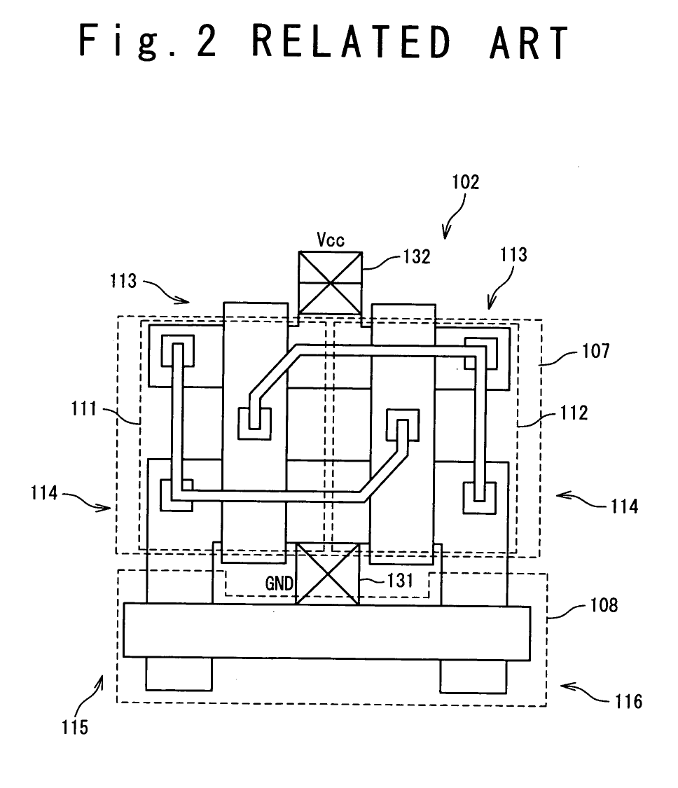

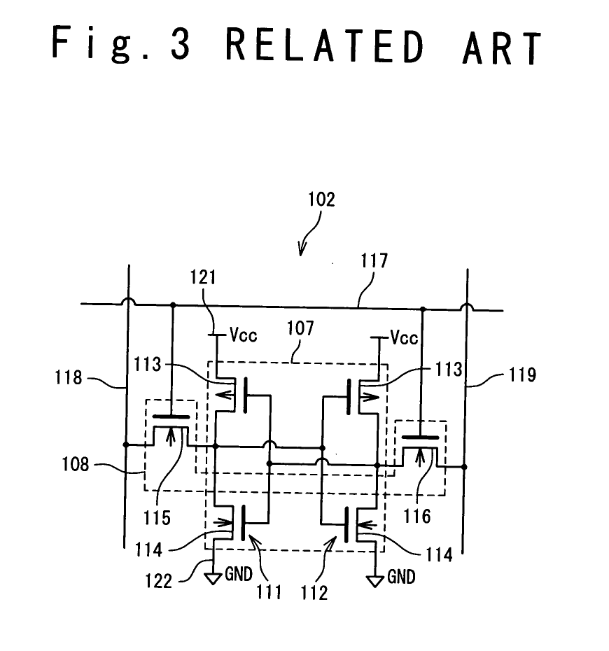

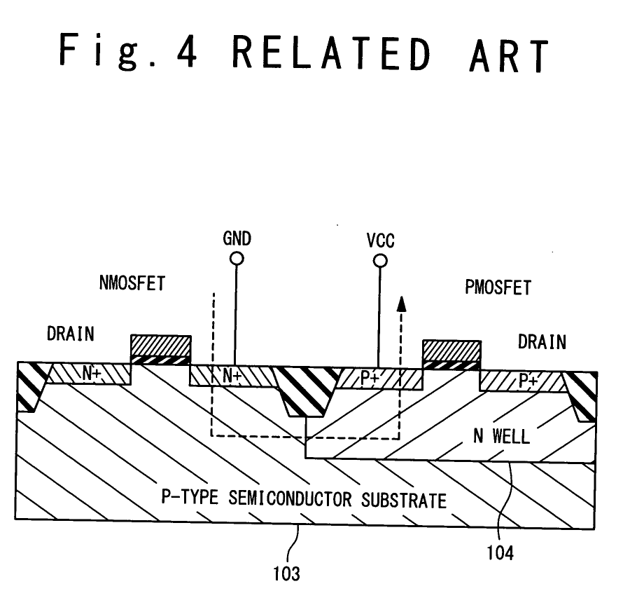

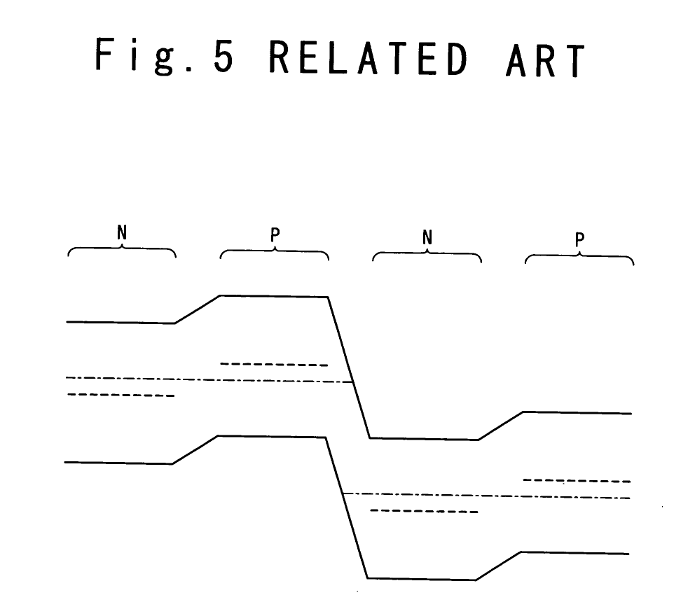

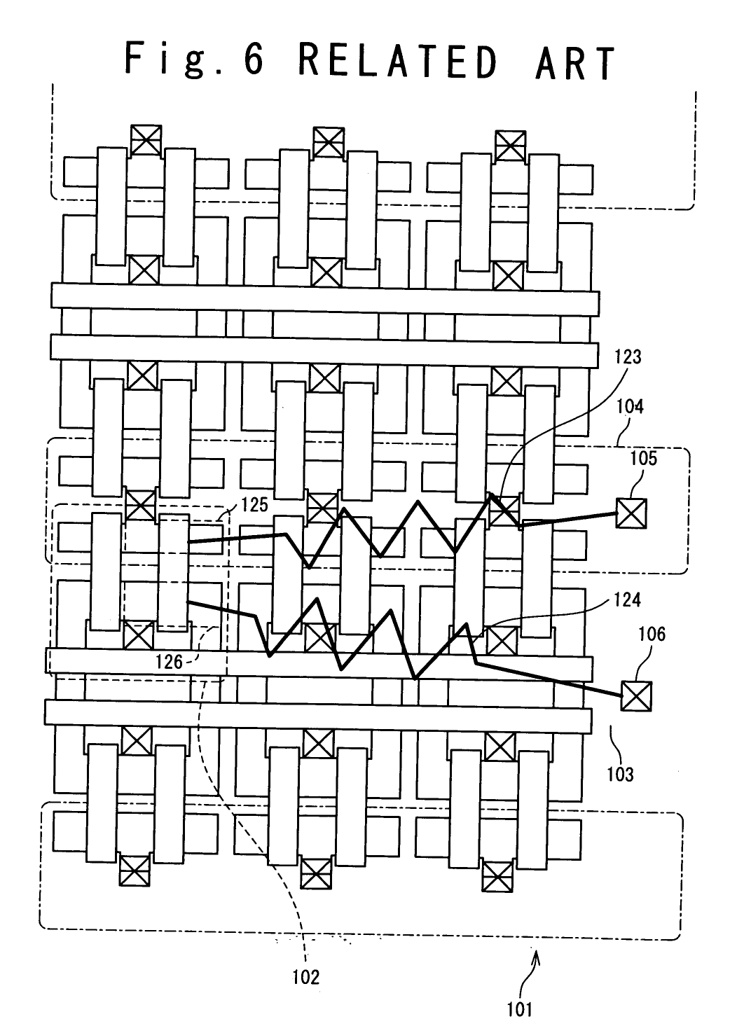

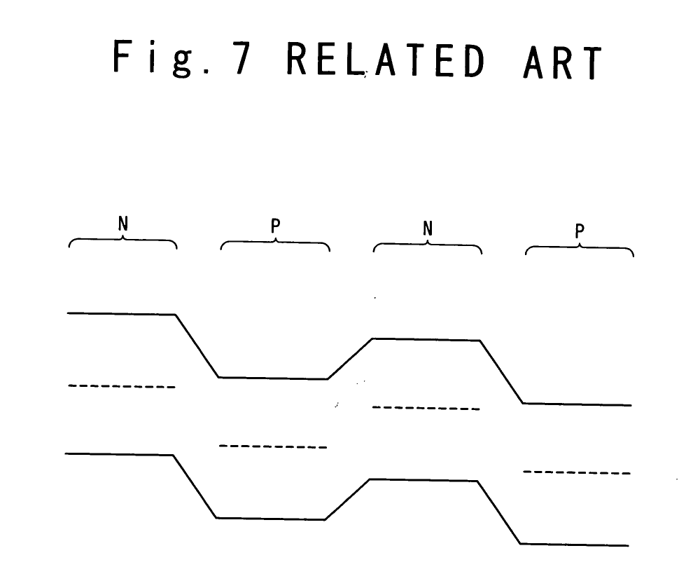

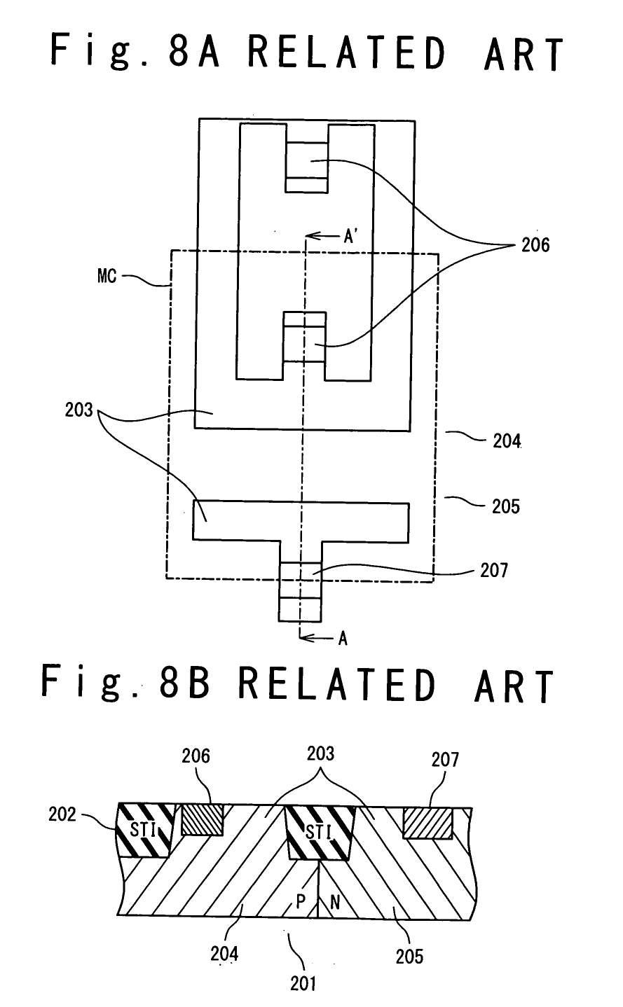

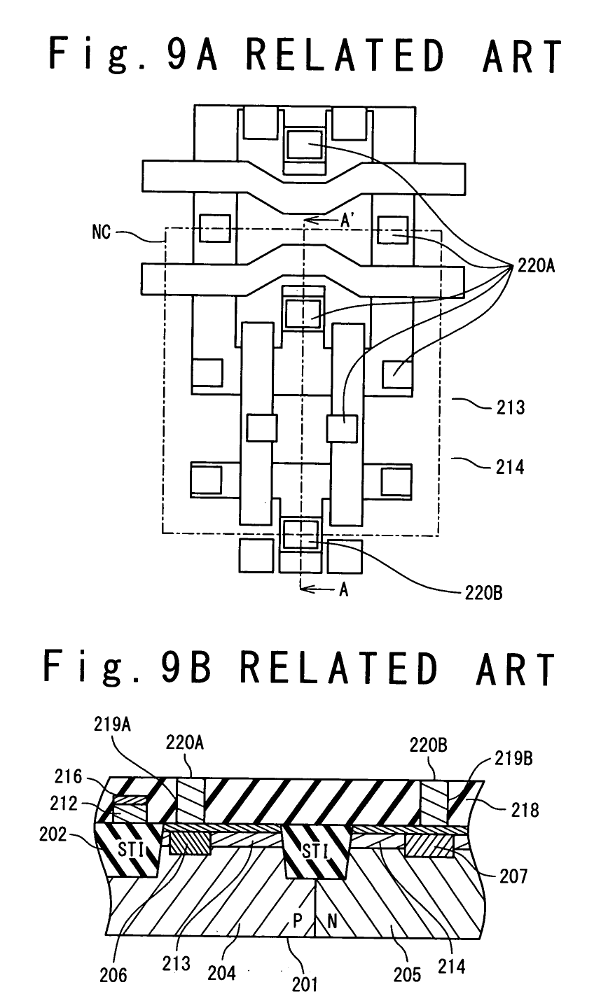

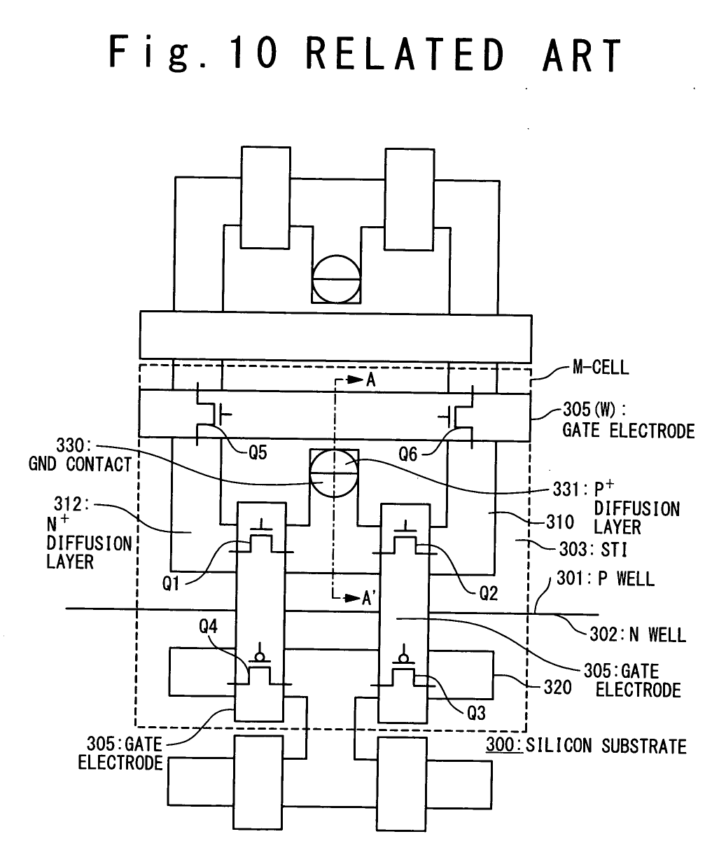

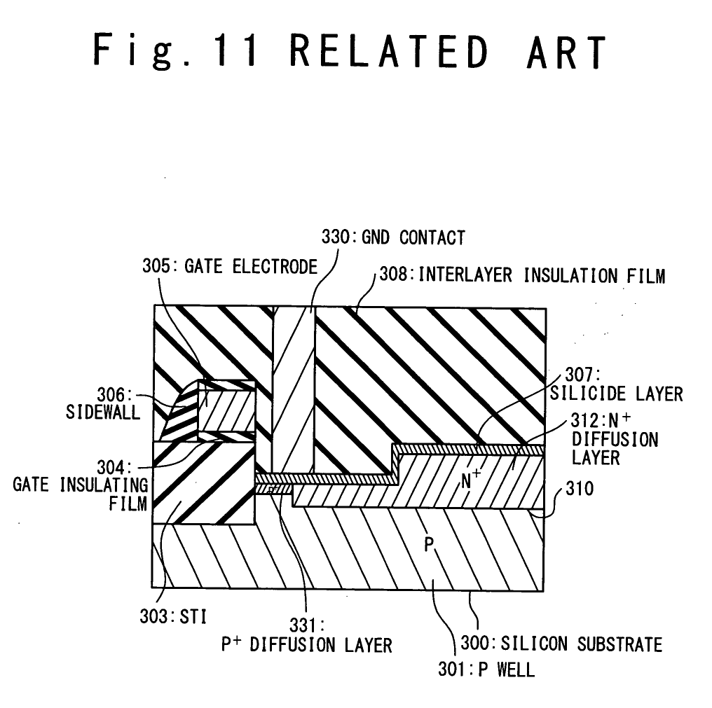

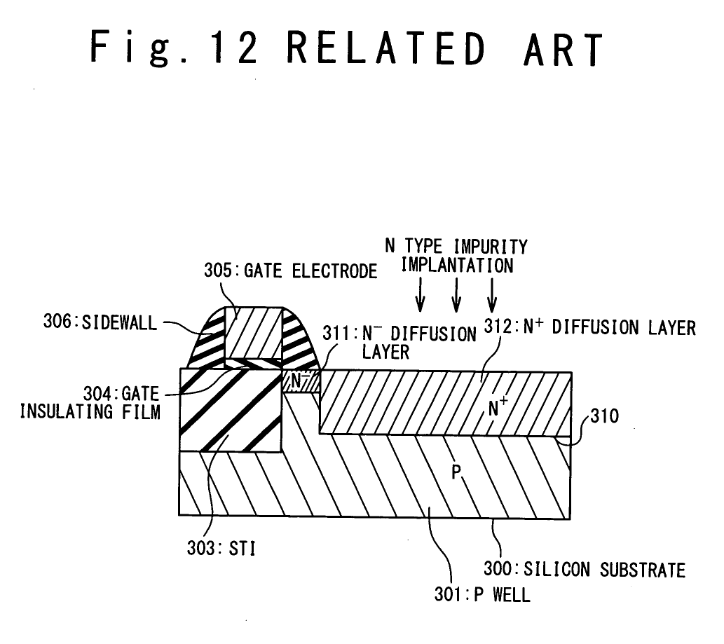

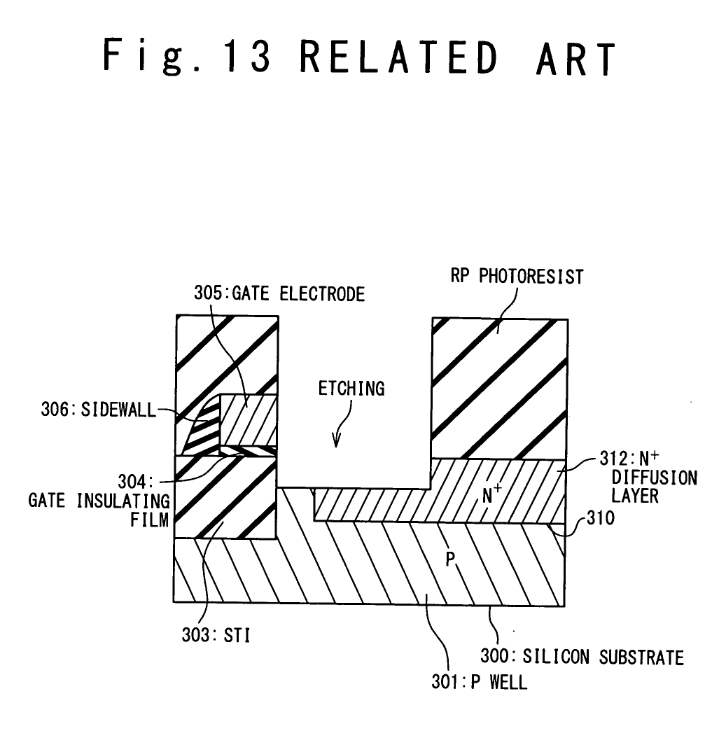

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

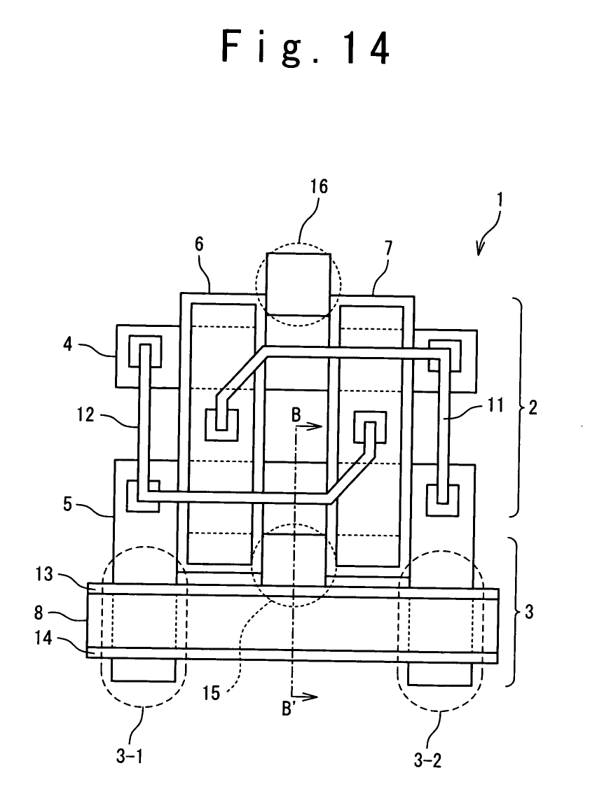

Embodiments according to the present invention will be described below referring to the drawings. FIG. 14 is a plan view exemplifying a layout of an SRAM cell 1 included in a semiconductor storage device of the present embodiment. The semiconductor storage device of the present embodiment includes a plurality of SRAM cells 1 being arranged in an array.

The SRAM cell 1 includes a flip-flop circuit 2 and an access control circuit 3. Moreover, the SRAM cell 1 is provided with a P-type activation region 4 and an N-type activation region 5. The P-type activation region 4 is connected to a power contact (not shown) though a power supply contact connection region 16. The N-type activation region 5 is connected to a ground contact (not shown) through a ground contact connection region 15.

The flip-flop circuit 2 is provided with a first inverter that operates in response to a voltage applied to a first inverter gate electrode 6 and a second inverter that operates in response to a voltage applied to a second inverter gate electrode 7. As shown in FIG. 14, the first inverter and the second inverter are connected with each other by wirings 11 and 12. Using these connections, the flip-flop circuit 2 constitutes a flip-flop circuit.

The access control circuit 3 includes the N-type activation region 5 and a polysilicon 8 for a word line. A sidewall 13 and a sidewall 14 are formed on both side surfaces of the polysilicon 8 for the word line. The access control circuit 3 includes a first access transistor 3-1 and a second access transistor 3-2. The first access transistor 3-1 and the second access transistor 3-2 are activated respectively in response to a voltage applied to the polysilicon 8 for the word line.

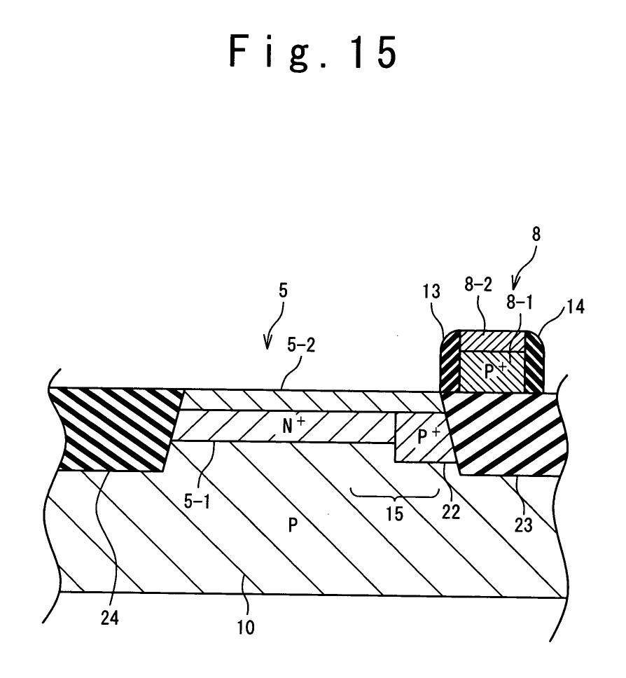

FIG. 15 is a sectional view exemplifying the SRAM cell 1. FIG. 15 illustrates a cross section of a line B-B′ in FIG. 14 described above. The SRAM cell 1 includes a first element isolation region 23 and a second element isolation region 24 that are formed in a P-type semiconductor substrate 10. Between the first element isolation region 23 and the second element isolation region 24, the N-type activation region 5 having the ground contact connection region 15 is formed. The N-type activation region 5 includes an N+ region 5-1 and a silicide 5-2. The polysilicon 8 for the word line is formed on the first element isolation region 23. The polysilicon 8 for the word line includes a polysilicon 8-1 and a silicide 8-2. Here, referring to FIG. 15, the ground contact connection region 15 of the SRAM cell 1 of the present embodiment is provided with the P+ semiconductor region 22. Moreover, the polysilicon 8 for the word line (the polysilicon 8-1) formed on the first element isolation region 23 has been implanted with P-type impurities.

Next, a method for manufacturing the semiconductor storage device of the present embodiment will be explained below. Incidentally, a plurality of SRAM cells 1 included in the semiconductor storage device is manufactured to have a same configuration. Therefore, in a manufacturing method described below, in order to make understanding of the present invention easy, the present embodiment will be explained referring to a layout diagram that extracts a part of the semiconductor storage device.

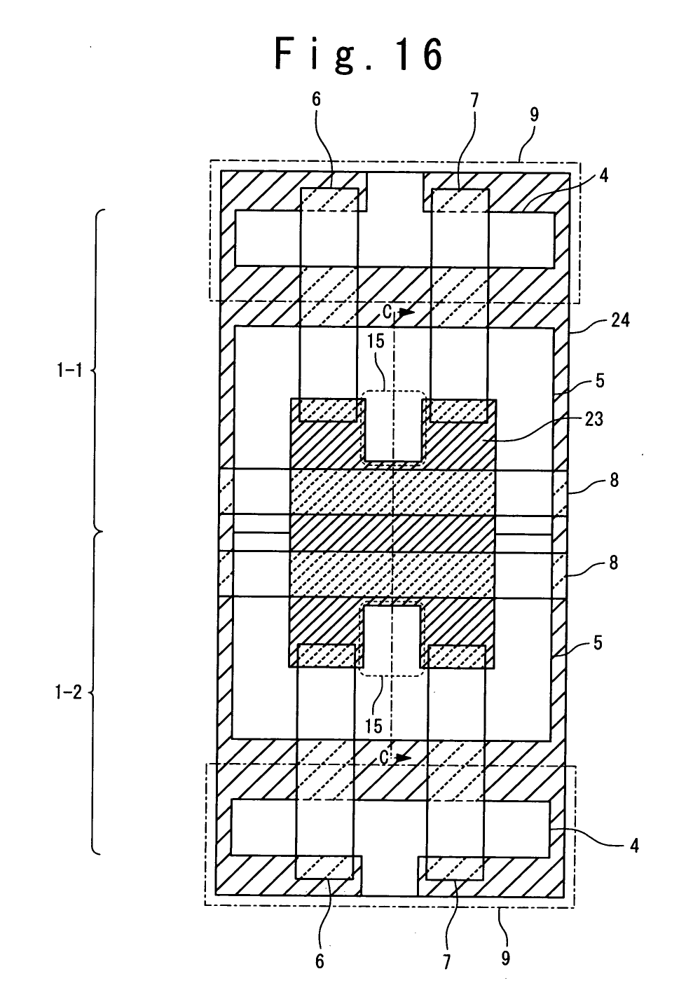

FIG. 16 is a plan view exemplifying a first step of a manufacturing process of the SRAM cell 1 included in the semiconductor storage device of the present embodiment. FIG. 16 illustrates a first step of a manufacturing process of the SRAM cell 1. FIG. 16 is a layout diagram showing a part of two bits. A first SRAM cell 1-1 and a second SRAM cell 1-2 are arranged symmetrically. A plurality of the layouts same as this figure is arranged in the right and left to constitute a memory cell array in the semiconductor storage device of the present embodiment.

In the first step of the manufacturing process of the SRAM cell 1, an N-well 9 is formed on the P-type semiconductor substrate 10 after forming the first element isolation region 23 and the second element isolation region 24. Then, the N-type activation region 5 and the P-type activation region 4 are formed selectively. Subsequently, a gate insulating film (not shown) is formed, and the first inverter gate electrode 6, the second inverter gate electrode 7, and the polysilicon 8 for the word line are formed. In order to connect with a gate polysilicon of the adjacent cell, the polysilicon 8 for the word line extends in the right and left directions, and also serves as a wiring of a word line.

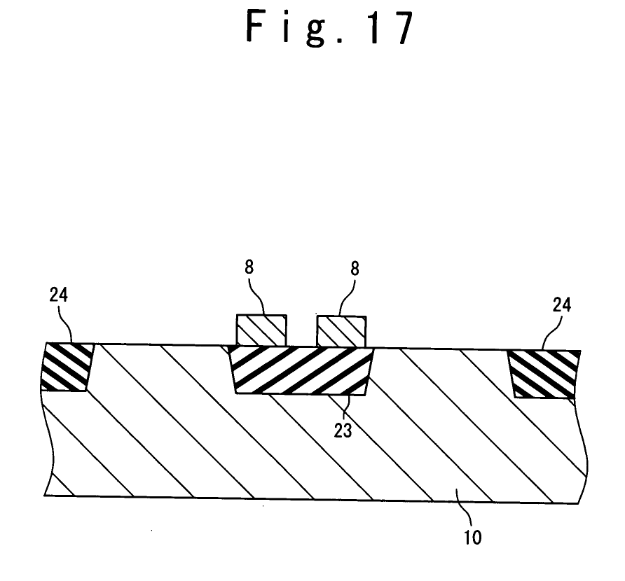

FIG. 17 is a sectional view exemplifying the SRAM cell 1 along a line C-C′ in FIG. 16 described above. As shown in FIG. 17, the polysilicon 8 for the word line is formed on the first element isolation region 23 in a region along the line C-C′. The first element isolation region 23 isolates the first SRAM cell 1-1 and the second SRAM cell 1-2.

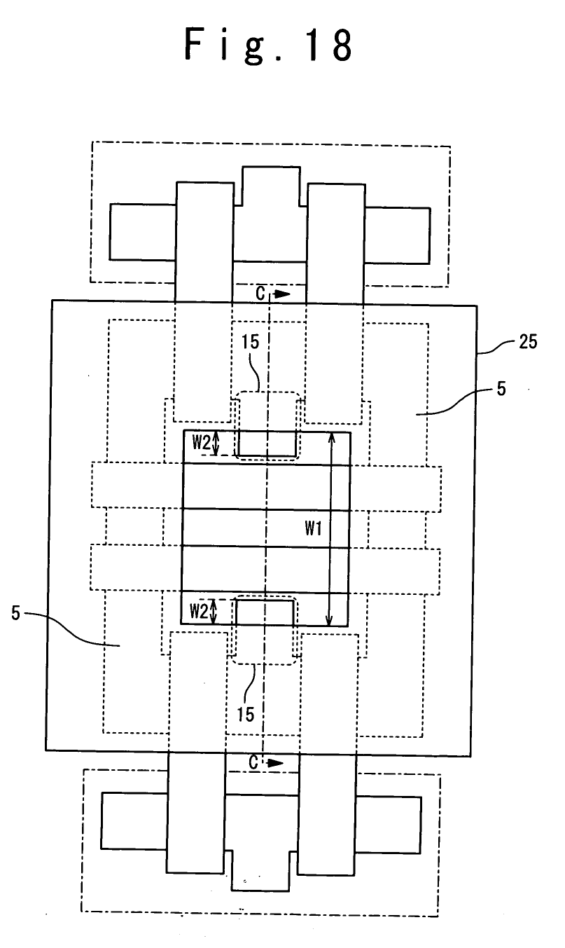

FIG. 18 is a plan view exemplifying a second step of the manufacturing process of the SRAM cell 1. As shown in FIG. 18, in the second step of the manufacturing process of the SRAM cell 1, a mask like a first resist layer 25 is selectively formed. Then, the P-type impurities, such as boron, are introduced into the substrate by ion implantation to form extensions of PMOSFETs.

At this time, the first resist layer 25 allows a part of the two ground contact connection regions 15 to be exposed. Here, the two ground contact connection regions 15 sandwich the polysilicons 8 for the word line therebetween. The two ground contact connection regions 15 are the ground contact connection region 15 of the first SRAM cell 1-1 and the ground contact connection region 15 of the second SRAM cell 1-2. Moreover, it is preferable that the first resist layer 25 is formed so as to cover the N-type activation regions 5 that will become diffusion layer regions of the NMOSFETs.

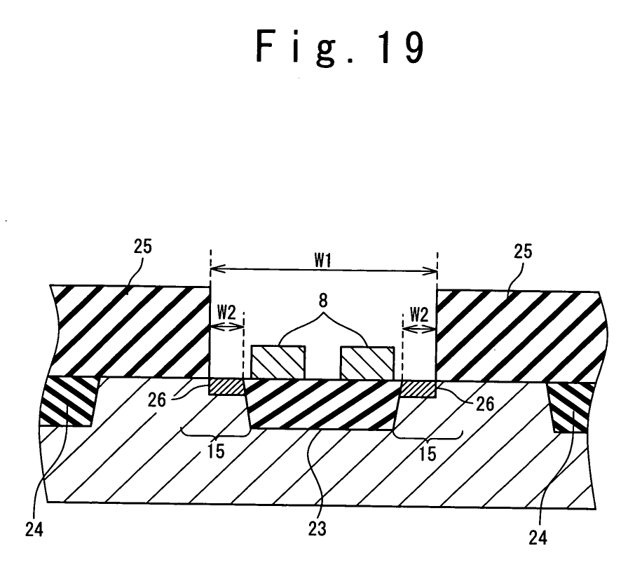

FIG. 19 is a sectional view exemplifying the SMAM cell 1 along a line C-C′ in FIG. 18 described above. As shown in FIG. 19, an opening of a width W1 is formed in the first resist layer 25. In the second step of the manufacturing process of the SRAM cell 1, a first P+ region 26 of a width W2 is formed by introducing the P-type impurities into the substrate from the opening. At this time, the P-type impurities are introduced also into the polysilicon 8 for the word line being exposed by the opening.

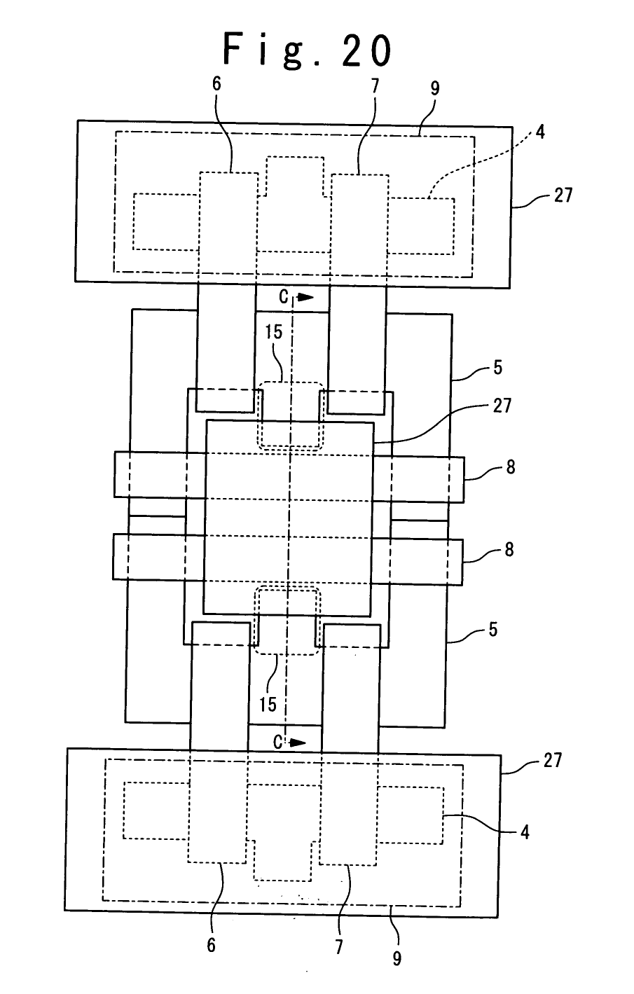

FIG. 20 is a plan view exemplifying a third step of the manufacturing process of the SRAM cell 1. As shown in FIG. 20, a mask like a second resist layer 27 is formed and N-type impurities, such as phosphorus, are introduced into the substrate by ion implantation to form extensions of NMOSFETs. At this time, the second resist layer 27 is formed so as to cover a part of the two ground contact connection regions 15 which sandwich the polysilicon 8 for the word line therebetween. Moreover, the second resist layer 27 is formed so as to expose (i.e., not to cover) the diffusion layer region of the NMOS. In other words, a portion where the second resist layer 27 in FIG. 20 covers approximately overlaps a portion where the first resist layer 25 in FIG. 18 does not cover.

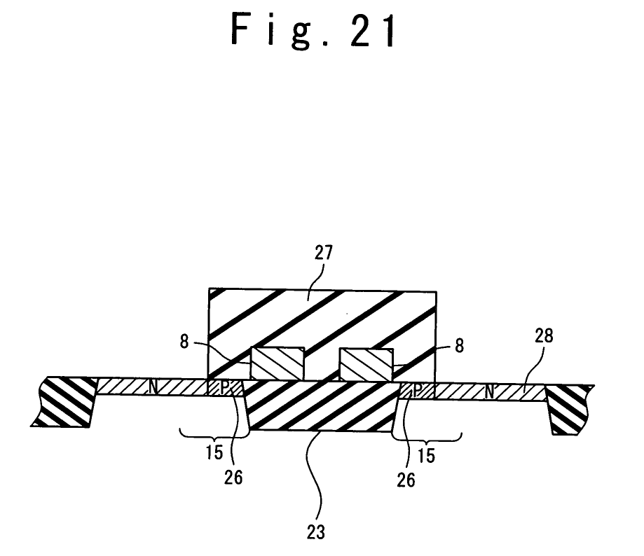

FIG. 21 is a sectional view exemplifying the SRAM cell 1 along the line C-C′ in FIG. 20 described above. As shown in FIG. 20, in the third step of the manufacturing process of the SRAM cell 1, first N+ regions 28 are formed in the ground contact connection regions 15. The first N+ region 28 contacts with the first P+ region 26. Incidentally, in the manufacturing method having been described above, even if the process (the second step) of forming the extensions of the PMOSFETs and the process (the third step) of forming the extensions of the NMOSFETs are performed in a reverse order, it is possible to obtain the effects of the present invention.

FIG. 22 is a plan view exemplifying a fourth step of the manufacturing process of the SRAM cell 1. In the fourth step, sidewalls are formed on side surfaces of the first inverter gate electrode 6, the second inverter gate electrode 7, and the polysilicon 8 for the word line. There are various methods as a method for forming the sidewall. In the present invention, there is no restriction regarding the method for forming the sidewall.

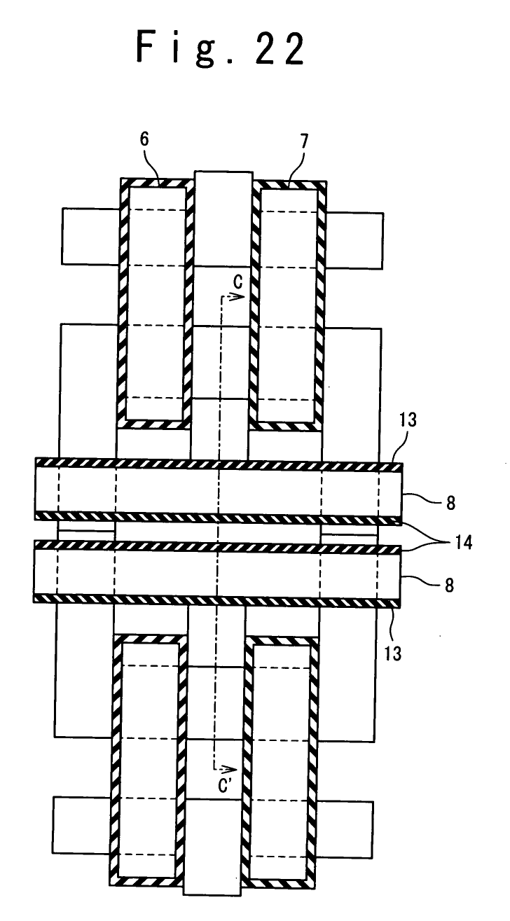

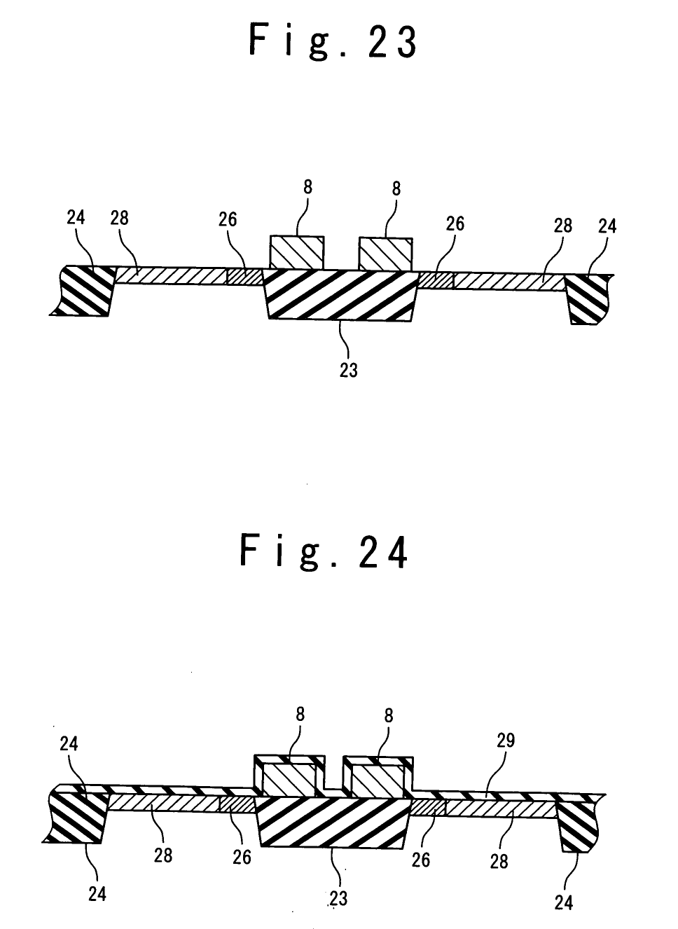

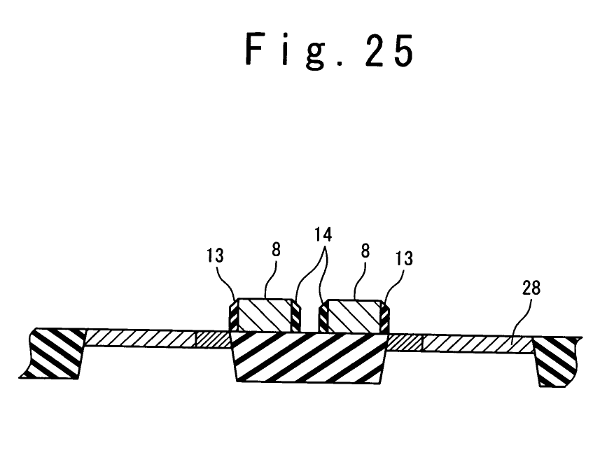

Below, an example of the method for forming the sidewall will be explained referring to drawings. FIGS. 23 to 25 are sectional views showing processes of forming the sidewalls. As shown in FIG. 23, after the first P+ region 26 and the first N+ region 28 are formed, a resist pattern is removed to expose surfaces of the polysilicon 8 for word line, the first P+ region 26, the first N+ region 28, the first element isolation region 23, and the second element isolation region 24. Subsequently, as shown in FIG. 24, an oxide film (silicon oxide) 29 is deposited, for example, by a chemical vapor deposition method (CVD method) on the whole surface of the SRAM cell 1. Next, as shown in FIG. 25, the oxide film (silicon oxide) 29 is etched back by anisotropic etching until the surface of the N-type activation region 5 and the surface of the polysilicon 8 for the word line are exposed. In this way, the sidewalls 13 and the sidewalls 14 are formed on the side surfaces of the polysilicon 8 for the word line.

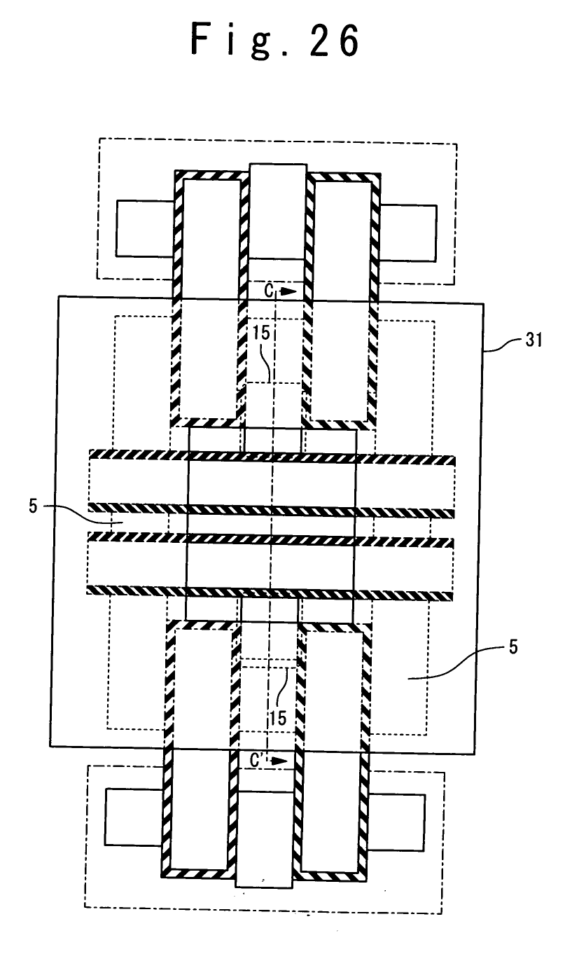

FIG. 26 is a plan view exemplifying a fifth step of the manufacturing process of the SRAM cell 1. In the fifth step, a mask is formed with a third resist layer 31, and the source and drain of the PMOS are formed. The third resist layer 31 allows a part of two ground contact connection regions 15 which sandwich the polysilicons 8 for the word line therebetween to be exposed. Here, two ground contact connection regions 15 are the ground contact connection regions 15 of the first SRAM cell 1-1 and the ground contact connection region 15 of the second SRAM cell 1-2. Moreover, it is preferable that the third resist layer 31 is formed so as to cover the N-type activation region 5 that will be the diffusion layer region of the NMOSFET. The source and drain of the PMOS are formed by ion-implanting, e.g., boron from the opening formed in the third resist layer 31.

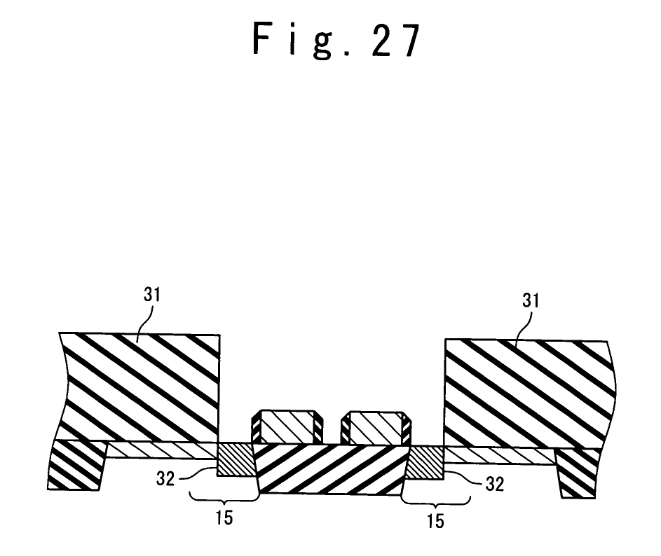

FIG. 27 is a sectional view exemplifying the SRAM cell 1 along the line C-C′ in FIG. 26 described above. As shown in FIG. 27, second P+ regions 32 are formed by the impurities being implanted from the opening of the third resist layer 31.

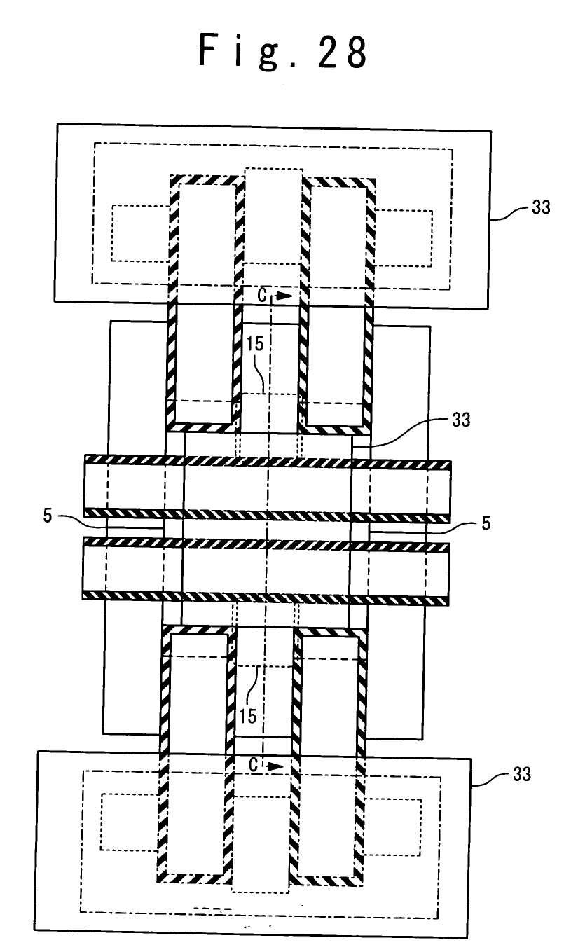

FIG. 28 is a plan view exemplifying a sixth step of the manufacturing process of the SRAM cell 1. In the sixth step, a mask is formed with a fourth resist layer 33, and the source and drain of the NMOS are formed. At this time, the fourth resist layer 33 is formed so as to cover a part of the two ground contact connection regions 15 which sandwich the polysilicon 8 for the word line therebetween. Moreover, the fourth resist layer 33 is formed so as to expose (i.e., not to cover) the diffusion layer region of the NMOS. In other words, a portion where the fourth resist layer 33 of FIG. 28 covers approximately overlaps a portion where the third resist layer 31 in FIG. 26 does not cover. In the sixth step, the source and drain of the NMOS are formed by ion-implanting the impurities (e.g., arsenic).

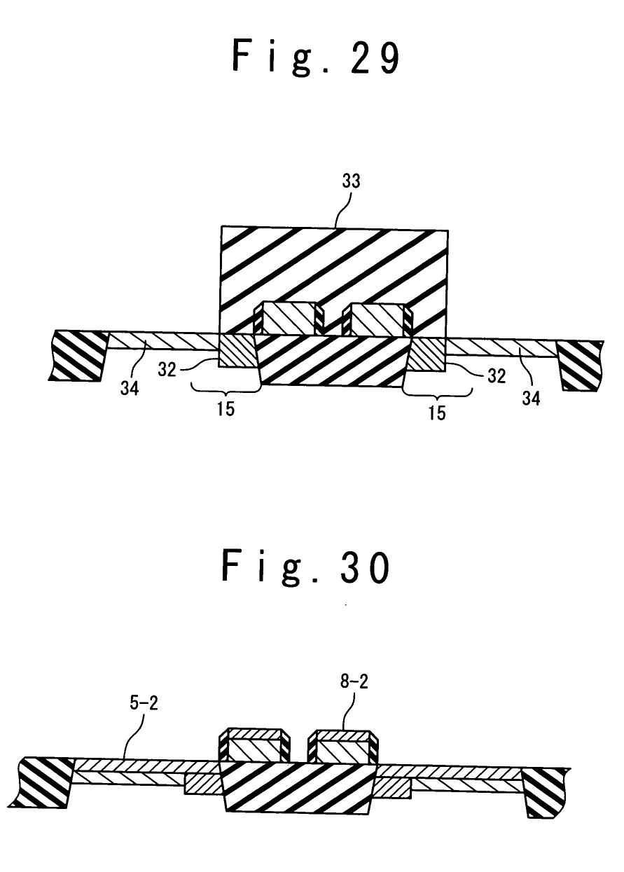

FIG. 29 is a sectional view exemplifying the SRAM cell 1 along the line C-C′ in FIG. 28 described above. As shown in FIG. 29, second N+ regions 34 are formed in regions that are not covered with the fourth resist layer 33. The second N+ region 34 is formed so as to contact with the second P+ region 32.

FIG. 30 is a sectional view exemplifying a seventh step of the manufacturing process of the SRAM cell 1. As shown in FIG. 30, in the seventh step, the SRAM cell 1 of the present embodiment is constructed by selectively forming silicide (the silicide 5-2, the silicide 8-2) on the surfaces of the diffusion layer and the gate polysilicon.

In the SRAM cell 1 of the present embodiment, the polysilicon 8 for the word line is P-type in a portion on the element isolation region 23. This P-type region does not reach as far as a field edge of the NMOS. Thus, in the SRAM cell 1 of the present embodiment, the polysilicon 8 for the word line that constitutes the NMOS is N-type. Therefore, the SRAM cell 1 of the present embodiment operates properly, without being dependent on a configuration of the polysilicon 8 for the word line located on the first element isolation region 23.

Incidentally, it is also possible to manufacture the SRAM cell 1 of the present embodiment by a method where a P-type diffusion region is not formed in a part of the ground contact connection region 15 (the part of the ground contact connection region 15 is not exposed) when the impurity implantation of the source and drain extension (SDE) is performed. For example, the following method may be adopted: when implanting impurities for forming the extension, the implantation of the P-type impurities to the ground contact connection region 15 is not performed, and when implanting the impurities for the source/drain, the implantation of the impurities is performed, with the ground contact connection region 15 partially covered and opened. In the manufacturing of the semiconductor storage device, the junction depth of the extension is shallower than that of the source and drain, and the concentration of the extension is lower than that of the source and drain, at the ion-implantation. Therefore, if the impurities are implanted differently according to positions when implanting the impurities for source/drain, the region implanted by the impurities is counter-doped by impurities of SD implantation; therefore, a contact can be formed in the P-well.

In the semiconductor storage device of the present embodiment, as described above, the resist pattern by a photoresist at the time of the ion implantation of forming the source and drain of the PMOS exposes a part of the GND contact and also exposes a part of the polysilicon for the word line simultaneously. Therefore, the resist pattern of this portion is given a comparatively large opening.

In a conventional semiconductor storage device, in order to give the opening only to a portion of the contact, a size of the opening must be made small. In order to form a pattern with the small-sized opening portion with the photoresist, light exposure must be made large. Therefore, in a process of photolithography of forming the resist pattern for the implantation of the extension and the implantation of the source and drain, it was not able to open such a small opening simultaneously.

In the semiconductor storage device of the present embodiment, a mask opening to the GND contact can be opened simultaneously at the time of the photolithography of forming the resist pattern for the implantation of the extension and the implantation of the source and drain by opening it as large as to include the polysilicon for word line.

According to the present invention, at the time of impurity implantation in a process of forming the source and drain, a connection part leading to the P-well (or P substrate) can be formed simultaneously. As a result, it is possible to construct the semiconductor storage device without preparing a new photomask.

Moreover, according to the present invention, it is possible to construct the semiconductor storage device without increasing a manufacturing process. Therefore, it is possible to suppress an increase in the manufacturing cost of an LSI.

Although the present invention has been described above in connection with several exemplary embodiments thereof, it would be apparent to those skilled in the art that those exemplary embodiments are provided solely for illustrating the present invention, and should not be relied upon to construe the appended claims in a limiting sense.

What is claimed is:

1. A semiconductor storage device comprising:
a storage circuit configured to store data;
an access control circuit configured to include a first access transistor and a second access transistor and control reading and writing of said data;
a ground voltage supplying region configured to supply a ground voltage to said storage circuit and said access control circuit; and
a polysilicon portion configured to connect a first gate electrode included in said first access transistor and a second gate electrode included in said second access transistor, and be composed of a semiconductor of a second conductive type,
wherein said ground voltage supplying region is connected to a ground voltage supplying contact which supplies said ground voltage, and includes:
a first portion configured to be composed of a semiconductor of said second conductive type, and
a second portion configured to be composed of a semiconductor of a first conductive type.

2. The semiconductor storage device according to claim 1, wherein said first gate electrode and said second gate electrode are composed of a polysilicon of said first conductive type.

3. The semiconductor storage device according to claim 2, wherein said polysilicon portion is formed on an element isolation region.

4. The semiconductor storage device according to claim 3, wherein each of said storage circuit and said access control circuit includes:
a NMOS transistor configured to be formed on a P-type silicon substrate,
wherein said ground voltage supplying region supplies said ground voltage to a source diffusion layer of said NMOS transistor through said first portion, while supplying said ground voltage to said P-type silicon substrate through said second portion.

5. The semiconductor storage device according to claim 4, wherein said first access transistor and said second access transistor execute reading and writing said data in response to voltages applied to said first gate electrode and said second gate electrode.

6. The semiconductor storage device according to claim 1, wherein said storage circuit includes:
a flip-flop circuit configured to be provided with a first inverter that operates in response to a voltage applied to a first inverter gate electrode and a second inverter that operates in response to a voltage applied to a second inverter gate electrode,
wherein said first inverter gate electrode is connected to said second access transistor and said second inverter gate electrode is connected to said first access transistor.

7. A manufacturing method of a semiconductor storage device having a SRAM cell, comprising:
forming a first photoresist having an opening portion in which a part of a contact connection region in an activated region where a transistor is formed and a polysilicon portion functions as a word line are exposed;
implanting first impurities of a second conductive type to said opening portion using said first photoresist as a mask;
forming a second photoresist masking a region where said first impurities are implanted; and
implanting second impurities of a first conductive type to said contact connection region using said second photoresist as a mask.

8. The manufacturing method of a semiconductor storage device according to claim 7, wherein said first photoresist forming step, includes:
masking a region where gate electrodes of NMOS transistors included in said SMAM cell is formed,using said first photoresist.

9. The manufacturing method of a semiconductor storage device according to claim 8, wherein said first impurities implanting step includes:
implanting said first impurities to said part of said contact connection region and said polysilicon portion simultaneously.

10. A semiconductor storage device comprising:
an access control circuit configured to include a first access transistor and a second access transistor and control reading and writing of data stored in a storage circuit;
a ground voltage supplying region configured to supply a ground voltage to said storage circuit and said access control circuit; and
a word line configured to have a connection portion which connects a first gate electrode included in said first access transistor and a second gate electrode included in said second access transistor,
wherein said ground voltage supplying region includes:
a first carrier type semiconductor configured to have first carriers as a majority carrier, and
a second carrier type semiconductor configured to have second carriers as a majority carrier,
wherein said connection portion includes impurities to make said first carriers be a majority carrier.

11. The semiconductor storage device according to claim 10, wherein said ground voltage supplying region supplies said ground voltage to a substrate through said first carrier type semiconductor, and supplies said ground voltage to diffusion layers of said storage circuit and said access control circuit through said second carrier type semiconductor.

12. The semiconductor storage device according to claim 10, wherein said storage circuit includes:
a flip-flop circuit configured to be provided with a first inverter that operates in response to a voltage applied to a first inverter gate electrode and a second inverter that operates in response to a voltage applied to a second inverter gate electrode, wherein said first inverter gate electrode is connected to said second access transistor and said second inverter gate electrode is connected to said first access transistor.
